(19) United States
(12) Patent Application Publication
(10) Pub. No.: US 2025/0163573 A1
(43) Pub. Date: May 22, 2025

(54) METHODS FOR FORMING MOLYBDENUM SURFACES WITH INCREASED DIFFUSION BARRIER

(71) Applicant: Applied Materials, Inc., Santa Clara, CA (US)

(72) Inventors: Zhijun CHEN, San Jose, CA (US); Jongbeom SEO, San Jose, CA (US); Fredrick FISHBURN, Belmont, CA (US); Raghuveer S. MAKALA, Campbell, CA (US)

(73) Assignee: Applied Materials, Inc., Santa Clara, CA (US)

(21) Appl. No.: 18/946,699

(22) Filed: Nov. 13, 2024

Related U.S. Application Data
(60) Provisional application No. 63/601,646, filed on Nov. 21, 2023.
(60) Provisional application No. 63/606,192, filed on Dec. 5, 2023.

(51) Int. Cl. C23C 16/34; C23C 16/04

(52) U.S. Cl. CPC C23C 16/34; C23C 16/045

(57) ABSTRACT

Semiconductor processing methods and semiconductor structures are provided with molybdenum-containing features. Methods include etching a substrate to form one or more shallow trench isolations and a plurality of vertically extending channels. Methods include forming one or more molybdenum-containing layers within one or more of the shallow trench isolations. Methods include contacting an exposed surface of the one or more molybdenum-containing layers with a nitrogen-containing precursor, where the contacting nitrides the exposed surface of the one or more molybdenum-containing layers, forming a protective layer over the one or more molybdenum-containing layers.

### CROSS-REFERENCES TO RELATED APPLICATIONS

This application claims the benefit of priority to U.S. Patent Application No. 63/601,646 filed on Nov. 21, 2023, and U.S. Patent Application No. 63/606,192 filed on Dec. 5, 2023, the contents of which are hereby incorporated by reference in their entirety for all purposes.

### TECHNICAL FIELD

The present technology relates to deposition and removal processes and chambers. More specifically, the present technology relates to systems and methods for improving oxygen diffusion into molybdenum surfaces.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. During formation and removal, materials may be subject to unintended damage and oxidation, which may result in wasted space as well as altered material properties. Such wasted area or material property change within a device becomes increasing problematic as devices continue to shrink.

Thus, there is a need for improved systems and methods that can be used to produce high quality devices and structures. These and other needs are addressed by the present technology.

### BRIEF SUMMARY

The present technology is generally directed to semiconductor processing methods. Methods include, providing a high aspect ratio semiconductor structure within a semiconductor processing chamber, where one or more molybdenum-containing layers are formed on the semiconductor structure. Methods include providing a nitrogen-containing precursor to a processing region of the semiconductor processing chamber. Methods include contacting the one or more molybdenum-containing layers with the nitrogen-containing precursor, where the contacting: nitrides a surface of the one or more molybdenum-containing layers, forming a protective layer over the one or more molybdenum-containing layers, or deposits the protective layer over the one or more molybdenum-containing layers.

In embodiments, methods include forming one or more dielectric layers over the protective layer, etching the molybdenum-containing layers, or a combination thereof. More embodiments include thermally annealing the molybdenum-containing layers at a temperature below or about 1000° C. Further embodiments include where a temperature within the semiconductor processing chamber is maintained at less than or about 1000° C. In more embodiments, the contacting is a plasma process, thermally driven, or a combination thereof. Furthermore, in embodiments, the contacting further includes a hydrogen containing precursor, a molybdenum-containing precursor, or a combination thereof. In yet more embodiments, the nitrogen-containing precursor includes NH₃, N₂, N₂ and H₂, or a combination thereof. Furthermore, in embodiments, the protective layer forms a conformal coating over the molybdenum-containing layer.

The present technology is also generally directed to methods of forming a vertical cell dynamic random-access memory (DRAM) array. Methods include etching a substrate to form one or more shallow trench isolations and a plurality of vertically extending channels. Methods include forming one or more molybdenum-containing layers within one or more of the shallow trench isolations. Methods include contacting an exposed surface of the one or more molybdenum-containing layers with a nitrogen-containing precursor, where the contacting: nitrides a surface of the one or more molybdenum-containing layers, forming a protective layer over the one or more molybdenum-containing layers, or deposits the protective layer over the one or more molybdenum-containing layers. Methods include forming one or more dielectric layers over the protective layer.

In embodiments, a temperature during contacting is maintained at less than or about 1000° C. In more embodiments, the protective layer forms a conformal coating over the molybdenum-containing layer. Furthermore, in embodiment, the contacting is a plasma process, thermally driven, or a combination thereof. Additionally or alternatively, in embodiments, the contacting further includes a hydrogen containing precursor, a molybdenum-containing precursor, or a combination thereof. Embodiments include where the nitrogen-containing precursor includes NH₃, N₂, N₂ and H₂, or a combination thereof. In further embodiments, the vertical cell dynamic random-access memory (DRAM) array includes a 4F² DRAM array. Moreover, in embodiments, the one or more molybdenum-containing layers includes one or more word lines. In embodiments, the one or more word lines include one or more word line sheets formed along at least a portion of a sidewall of the one or more vertically extending channels. Furthermore, in embodiments, methods include thermally processing the vertical cell DRAM array after forming the one or more dielectric layers over the protective layer.

The present technology is also generally directed to memory devices. Devices include a bit line extending in a first direction, two or more word lines extending in a second direction different than the first direction; and at least one channel extending between adjacent word lines in a direction generally orthogonal to the first direction and the second direction. Devices include where the channel has a first end adjacent to the bit line and a second end opposite the first end. Devices include where the two or more word lines include a molybdenum-containing material. In embodiment, devices include a MoₓN_{y} layer between the molybdenum-containing material and a dielectric material. Furthermore, in embodiment, the or more word lines include word line sheets. In yet more embodiments, the two or more word lines include filled trenches.

Such technology may provide numerous benefits over conventional processing methods. For example, methods and systems as discussed herein may provide one or more molybdenum layers that are protected from damage and oxidation during further processing. Furthermore, the methods and systems discussed herein may provide protected molybdenum layers without increasing a thickness of the molybdenum layer. Thus, the present technology may provide one or more structures having a thin molybdenum layer, such as one or more molybdenum word lines or bit lines, as examples only.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing chamber according to embodiments of the present technology.

FIG. 1B illustrates a top view of a conventional 4F² memory array.

FIG. 1C illustrates a perspective view of a conventional 4F² memory array.

FIG. 2 shows selected operations in a formation method according to embodiments of the present technology.

FIGS. 3A and 3B show cross-sectional views of a semiconductor structure according to embodiments of the present technology.

FIGS. 4A and 4B show cross-sectional views of a semiconductor structure according to embodiments of the present technology.

Several of the figures are included as schematics. It is to be understood that the figures are for illustrative purposes and are not to be considered of scale unless specifically stated to be of scale. Additionally, as schematics, the figures are provided to aid comprehension and may not include all aspects or information compared to realistic representations and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Historically, DRAM chip bit densities were increasing by approximately 25% node over node. However, the node over node increase in bit density has trended down to approximate 20% over the more recent generations, mainly due to the challenges with scaling the cell area. Cell design architecture for modern DRAM technology has been based on 6F² geometry, where F is the minimum feature size for a given technology node. Switching from 6F2 to 4F2 cell architecture could result in a 33% increase in bit density at the same technology node. In addition, patterning difficulties for 4F2 DRAM are greatly reduced as compared to 6F². This is mainly because in the 4F² DRAM scheme capacitor and bit line are located at two ends of a vertical cell transistor, instead of tightly packed on the same side as in 6F² DRAM.

However, 4F² DRAM design comes with its own challenges. For example, 4F2 memory cells have the transistor channel disposed between the bitline and the capacitor layers, so there is no common substrate connecting the channels, resulting in a floating body effect for these transistors. Moreover, such design schemes are also capable of producing high aspect ratio structures that challenge existing doping techniques. Namely, similar challenges are experienced in similar structures, such as 3D DRAM, 3D NAND, and the like, as attempts to further increase chip densities intensify.

One such effort includes utilizing materials with improved properties. For instance, there is a demand in the industry to utilize materials that have low resistivities, such as word line and/or bit line materials. For instance, there is a desire to utilize molybdenum as a low resistivity material. However, molybdenum is highly susceptible to damage, as well as oxygen and nitrogen inter-diffusion during device processing, which can decrease the benefits provided by low resistivity materials. Attempts have been made to passivate molybdenum in order to protect the layer from damage and inter-diffusion, but existing attempts have either increased the resistivity, such as by utilizing large amounts of the molybdenum material to form the protective layer, or proven unsuitable for modern chip designs. Namely, existing passivation methods drastically increase the thickness of the layer, which is not feasible when working within modern chip features, due to the limited space available.

The present technology overcomes these and other problems by providing a method for forming a protective layer over one or more molybdenum layers without damaging the molybdenum or increasing the thickness of the layer(s). Furthermore, the present technology may form the layer in a conformal manner on the surface of the molybdenum layer, allowing a thin but complete protection layer to be formed. In embodiments, the protective layer may include forming a molybdenum nitride, and may not require a cleaning operation prior to formation of the protective layer. In addition, structures and methods according to the present technology may revert the protective layer to metallic molybdenum after formation of one or more additional layers. Thus, the present technology may provide for the use of low resistivity materials with a decreased risk of damage and inter-diffusion, even when the resulting device contains one or more high aspect ratio or otherwise complex features.

Although the remaining disclosure will routinely identify specific formation, deposition, and etch processes utilizing the disclosed technology, it will be readily understood that the systems and methods are equally applicable to other deposition and etch chambers, as well as processes as may occur in the described chambers. Accordingly, the technology should not be considered to be so limited as for use with these specific deposition processes or chambers alone. The disclosure will discuss one possible system and chamber that may be used to perform deposition processes according to embodiments of the present technology before additional details according to embodiments of the present technology are described.

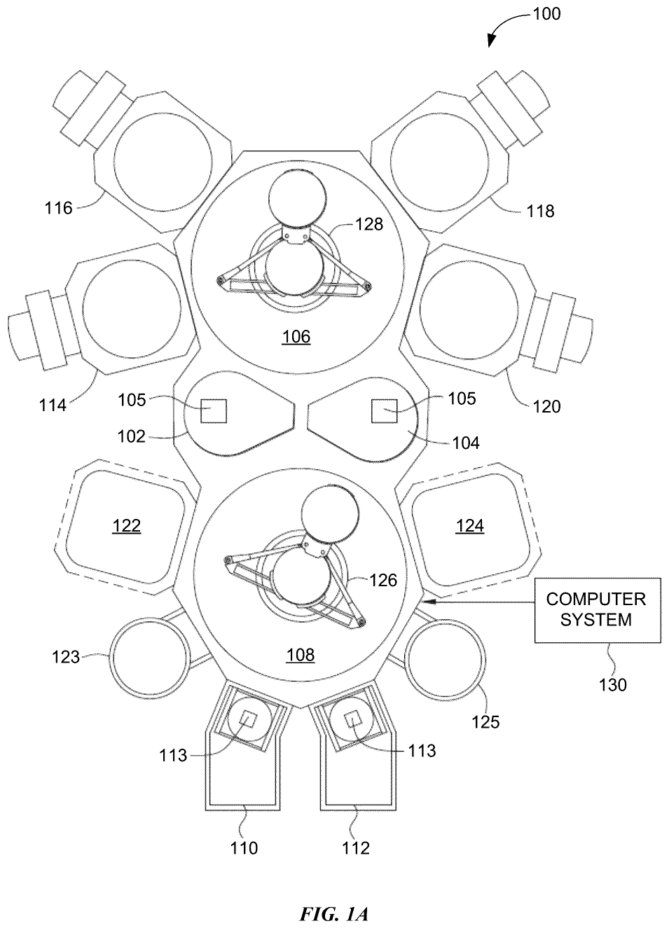

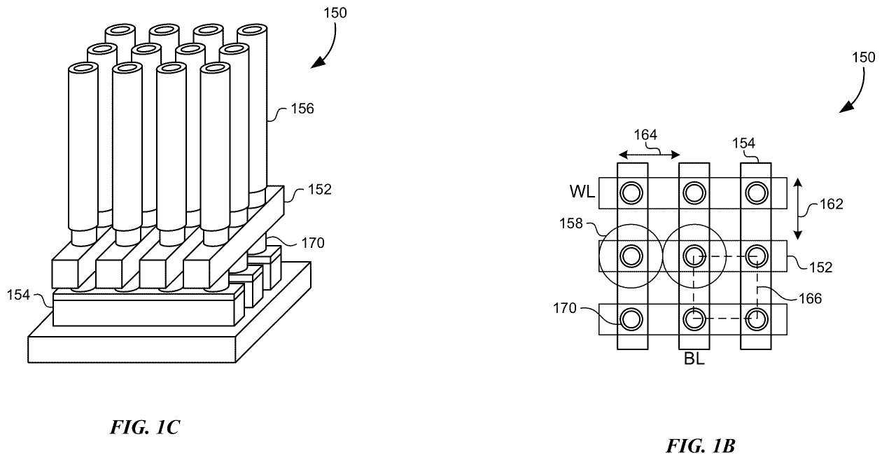

FIG. 1A illustrates a top plan view of a multi-chamber processing system 100, which may be specifically configured to implement aspects or operations according to some embodiments of the present technology. The multi-chamber processing system 100 may be configured to perform one or more fabrication processes on individual substrates, such as any number of semiconductor substrates, for forming semiconductor devices. The multi-chamber processing system 100 may include some or all of a transfer chamber 106, a buffer chamber 108, single wafer load locks 110 and 112, although dual load locks may also be included, processing chambers 114, 116, 118, 120, 122, and 124, preheating chambers 123 and 125, and robots 126 and 128. The single wafer load locks 110 and 112 may include heating elements 113 and may be attached to the buffer chamber 108. The processing chambers 114, 116, 118, and 120 may be attached to the transfer chamber 106. The processing chambers 122 and 124 may be attached to the buffer chamber 108. Two substrate transfer platforms 102 and 104 may be disposed between transfer chamber 106 and buffer chamber 108, and may facilitate transfer between robots 126 and 128. The platforms 102, 104 can be open to the transfer chamber and buffer chamber, or the platforms may be selectively isolated or sealed from the chamber to allow different operational pressures to be maintained between the transfer chamber 106 and the buffer chamber 108. Transfer platforms 102 and 104 may each include one or more tools 105, such as for orientation or measurement operations.

The operation of the multi-chamber processing system 100 may be controlled by a computer system 130. The computer system 130 may include any device or combination of devices configured to implement the operations described below. Accordingly, the computer system 130 may be a controller or array of controllers and/or a general purpose computer configured with software stored on a non-transitory, computer-readable medium that, when executed, may perform the operations described in relation to methods according to embodiments of the present technology. Each of the processing chambers 114, 116, 118, 120, 122, and 124 may be configured to perform one or more process steps in the fabrication of a semiconductor structure. More specifically, the processing chambers 114, 116, 118, 120, 122, and 124 may be outfitted to perform a number of substrate processing operations including dry etch processes, cyclical layer deposition, atomic layer deposition, chemical vapor deposition, physical vapor deposition, etch, pre-clean, degas, orientation, among any number of other substrate processes.

FIGS. 1B and 1C illustrate top and perspective views of a conventional 4F² memory array 150. The memory array 150 may include a plurality of word lines 152 that are arranged in a first layer over a substrate. The word lines 152 may be conductive traces that are used to select a word line of memory cells in the memory array 150. The memory array 150 may also include a plurality of bit lines 154 arranged in a second layer over a substrate. The plurality of bit lines may be conductive traces that are used to select a bit line of memory cells in the memory array 150. Activating one of the plurality of bit lines 154 and one of the plurality of word lines 152 may select an individual cell in the memory array 150. The first layer and the second layer may include different metal layers formed at different times during manufacturing process. For example, the first layer with the word lines 152 may be formed above the second layer with the bit lines 154 such that the two layers do not intersect.

A plurality of vertical memory cells may be arranged over intersections between the plurality of word lines 152 and the plurality of bit lines 154. Each of the plurality of vertical memory cells may include a vertical transistor 170, which may be referred to as a vertical pillar transistor or vertical column transistor. A channel material for the transistor may be formed from a single-crystal silicon pillar, or any other substrates discussed in greater detail below. This silicon channel may be formed by etching the substrate. Each of the plurality of vertical memory cells may also include a vertical capacitor 156. The vertical memory cell may operate by storing a charge on the vertical capacitors 156 to indicate a saved memory state. However, while FIGS. 1B and 1C illustrate the arrangement of the vertical transistors and capacitors in a rectangular orthogonal grid pattern, it should be understood that other orientations are contemplated for use with the present technology. For instance, in embodiments, the capacitors and vertical transistors may be spaced in alternating rows that are offset by one half the distance between the vertical transistors. Namely, a first row of memory cells may be regularly spaced apart in a line in a first direction, and a second row of memory cells may also be regularly spaced apart in a line also in the first direction, but the second row of memory cells may be offset from the first row of memory cells, such as aligned approximately halfway between the vertical transistors and capacitors of the first row, in embodiments. Such a pattern may be referred to as a “honeycomb” or “hexagonal pattern” as compared to the square pattern illustrated in FIGS. 1B and 1C. Thus, it should be understood that any suitable orientation may be utilized with the present technology.

It is useful to characterize the dimensions of the unit cell area 166. For example, a capacitor footprint 158 may be defined as a circular area around each vertical capacitor 156. The capacitor footprint 158 may include the horizontal cross-sectional area of the capacitor expanded out until the cross-sectional area contacts a capacitor area from a neighboring memory cell. Assuming that the word line pitch 162 for the plurality of word lines 152 and the bit line pitch 164 for the plurality of bit lines 154 may be defined as 2F. This leads to an overall cross-sectional area of 4F² for a unit cell area 166. However, while a 4F2 unit memory arrays have been discussed herein, it should be clear that the processes and systems are applicable to other memory arrays discussed above.

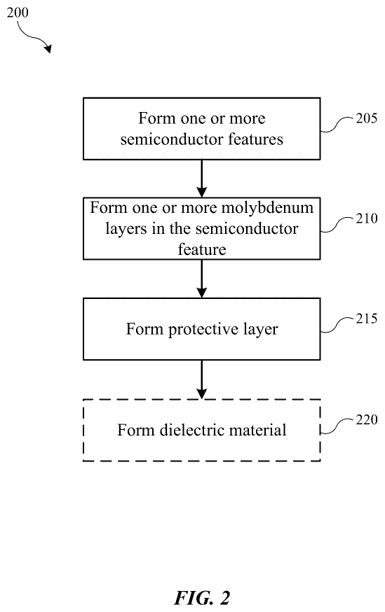

FIG. 2 shows exemplary operations in a method 200 according to some embodiments of the present technology. The method may be performed in a variety of processing chambers, including processing chamber 100 described above. Method 200 may include a number of optional operations, which may or may not be specifically associated with some embodiments of methods according to the present technology. For example, while it should be clear that the precursor semiconductor structure 300 described herein may be utilized to advantageously form a variety of challenging structures, precursor structure 300, as well as semiconductor structure 400 may illustrate exemplary structures, and methods of forming such structures, only. Furthermore, it should be clear that these exemplary structures and methods of forming such structures are non-limiting and that further structures as well as methods of forming such structures are contemplated.

Method 200 may include additional operations prior to initiation of the listed operations. For example, additional processing operations may include forming structures on a semiconductor substrate, which may include both forming and removing material. Prior processing operations may be performed in the chamber in which method 200 may be performed, or processing may be performed in one or more other processing chambers prior to delivering the substrate into the semiconductor processing chamber in which method 200 may be performed.

Regardless, method 200 may optionally include delivering a semiconductor substrate to a processing region of a semiconductor processing chamber, such as processing chamber 100 described above, or other chambers that may include components as described above. The substrate may be deposited on a substrate support/transfer platform, which may be a pedestal such as substrate support 104, and which may reside in a processing region of the chamber, such as processing region of processing chamber 120 described above. Method 200 describes operations shown schematically in the remaining figures, the illustrations of which will be described in conjunction with the operations of method 200. It is to be understood that the figures illustrate only partial schematic views, and a semiconductor substrate may include further components as illustrated in the figures, as well as alternative components, of any size or configuration that may still benefit from aspects of the present technology.

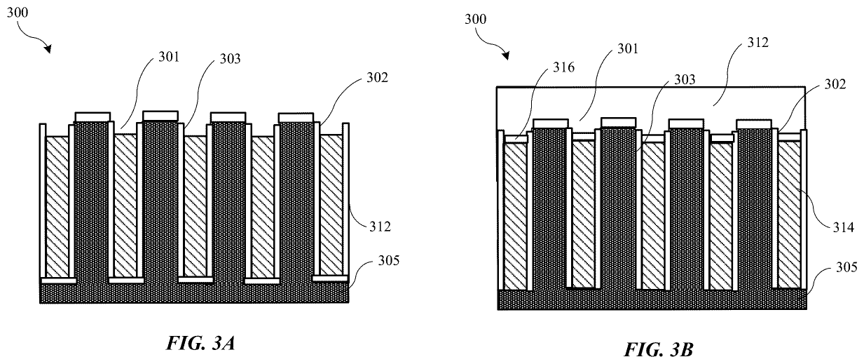

Method 200 may or may not involve optional operations to develop the semiconductor structure to a particular fabrication operation. It is to be understood that method 200 may be performed on any number of semiconductor structures 300 or substrates 302, as illustrated in the figures, including exemplary structures on which a selective deposition material may be formed. As illustrated in FIG. 3A substrate 305 may be any number of materials, such as a base wafer or substrate made of silicon or silicon-containing materials, germanium, other substrate materials, as well as one or more materials that may be formed overlying the substrate during semiconductor processing.

Moreover, while various deposition and fill processes will be described, it should be understood that, in embodiments, the semiconductor structure may be transferred to and between one or more process chambers 114, 116, 118, 120, 122, and 124 configured for deposition and/or fill processes, including chambers for: chemical vapor deposition (CVD), physical vapor deposition (PVD), atomic layer deposition (ALD), plasma-enhanced chemical vapor deposition (PECVD), plasma enhanced atomic layer deposition (PEALD), or the like. Thus, unless specified, it should be understood that any one or more of the above methods may be utilized as known in the art. Similarly, the semiconductor structure may be transferred to and between one or more process chambers 114, 116, 118, 120, 122, and 124 configured for etching, such as one or more of inductively coupled plasma (ICP) etching, reactive ion etching (RIE), capacitively coupled plasma (CCP) etching, or the like, as well as other etching processes as known in the art.

In embodiments, the substrate 305 may include bulk substrates, epitaxially grown substrates, and/or silicon on insulator wafer. As used herein, the term “semiconductor substrate” refers to a substrate in which the entirety of the substrate is comprised of a semiconductor material. The semiconductor substrate may include any suitable semiconducting material and/or combinations of semiconducting materials for forming a semiconductor structure. For example, the semiconducting layer may comprise one or more materials such as crystalline silicon (e.g., Si<100> or Si<111>), silicon oxide, strained silicon, silicon germanium, doped or undoped polysilicon, doped or undoped silicon wafers, patterned or non-patterned wafers, doped silicon, germanium, gallium arsenide, or other suitable semiconducting materials. In embodiments, the semiconductor material is silicon (Si). In one or more embodiments, the semiconductor substrate 300 includes a semiconductor material, e.g., silicon (Si), carbon (C), germanium (Ge), silicon germanium (SiGe), germanium tin (GeSn), other semiconductor materials, or any combination thereof. In one or more embodiments, the substrate 305 includes one or more of silicon (Si), germanium (Ge), gallium (Ga), arsenic (As), or phosphorus (P). Although a few examples of materials from which the substrate may be formed are described herein, any material that may serve as a foundation upon which passive and active electronic devices (e.g., transistors, memories, capacitors, inductors, resistors, switches, integrated circuits, amplifiers, optoelectronic devices, or any other electronic devices) may be built falls within the spirit and scope of the present disclosure.

In embodiments, the semiconductor material may be a doped material, such as n-doped silicon (n-Si), or p-doped silicon (p-Si). In embodiments, the substrate may be doped using any suitable process such as an ion implantation process. As used herein, the term “n-type” refers to semiconductors that are created by doping an intrinsic semiconductor with an electron donor element during manufacture. The term n-type comes from the negative charge of the electron. In n-type semiconductors, electrons are the majority carriers and holes are the minority carriers. As used herein, the term “p-type” refers to the positive charge of a well (or hole). As opposed to n-type semiconductors, p-type semiconductors have a larger hole concentration than electron concentration. In p-type semiconductors, holes are the majority carriers and electrons are the minority carriers. However, as discussed above, in embodiments, the substrate may include on or more layers or materials, based upon the desired end structure.

For instance, semiconductor structure 300 may contain a stack of alternating layers of materials, which in some embodiments may be used in 3D DRAM memory formation or a vertically extending orientation, such as for 4F² memory formation. Nonetheless, in embodiments, method 200 may include forming one or more features 301 in semiconductor structure 300. In FIG. 3A, the one or more features may include on one or more trenches 301 defining one or more channels 302 that may extend between adjacent features 301. While the figures are shown with features 301 extending vertically, it should be clear that the structure 300 may include a 3D DRAM structure, and the one or more channels 302 may extend in a generally horizontal direction, and be generally perpendicular to a bit line. Furthermore, in embodiments, the one or more features 301 may vary based upon the desired final device.

Nonetheless, in the vertical orientation of FIG. 3A, the channels 302 may extend in a generally vertical direction and be generally perpendicular to the substrate 305. For instance, in embodiments, the one or more channels 302 may be within about 10° from perpendicular with substrate 305, such as less than or about 7.5°, such as less than or about 5°, such as less than or about 2.5°, such as less than or about 1° from perpendicular, or any ranges or values therebetween. In embodiments, the one or more channels 302 and substrate 305 may be perpendicular to one another.

However, it should be clear that the methods and systems discussed herein can also be used to form any semiconductor structure which contains a molybdenum layer adjacent to a dielectric layer, such as a dielectric layer containing oxygen and/or nitrogen. Thus, the present technology may be utilized to replace conventional metallized features that usually include titanium nitride or tungsten, as examples. For example, methods and systems discussed herein may also suitable for forming molybdenum features in current 6F2 DRAM, 3D DRAM, 3D NAND, to name a few.

Nonetheless, in embodiments, the one or more channels 302 may have a depth of greater than or about 50 nm, such as greater than or about 100 nm, such as greater than or about 150 nm, such as greater than or about 200 nm, such as greater than or about 250 nm, such as greater than or about 300 nm, such as greater than or about 400 nm, greater than or about 500 nm, greater than or about 600 nm, greater than or about 700 nm, or more, or any ranges or values therebetween.

The one or more channels may have a width or thickness of greater than or about 1 nm, such as greater than or about 2 nm, greater than or about 3 nm, greater than or about 4 nm, greater than or about 5 nm, greater than or about 6 nm, greater than or about 7 nm, greater than or about 8 nm, greater than or about 9 nm, greater than or about 10 nm, greater than or about 12 nm, greater than or about 14 nm, greater than or about 16 nm, greater than or about 18 nm, or such as less than or about 30 nm, such as less than or about 28 nm, such as less than or about 26 nm, such as less than or about 24 nm, such as less than or about 22 nm, such as less than or about 20 nm, such as less than or about 15 nm, such as less than or about 10 nm, or any ranges or values therebetween.

Thus, in embodiments, the channel and/or adjacent features 301 may be considered to have a high aspect ratio, such as an aspect ratio of greater than or about 10, such as greater than or about 20, such as greater than or about 30, such as greater than or about 40, such as greater than or about 50, such as greater than or about 60, such as greater than or about 70, such as greater than or about 80, such as greater than or about 90, such as greater than or about 100, such as greater than or about 150, or any ranges or values therebetween.

However, as discussed above, in embodiments, the one or more channels may not have a high aspect ratio or a large height. Instead, the channel may be located in a device having limited horizontal distance (e.g. feature width) within the feature, such as less than or about 60 nm, such as less than or about 50 nm, such as less than or about 40 nm, such as less than or about 30 nm, such as less than or about 20 nm, such as less than or about 10 nm, such as less than or about 9 nm, such as less than or about 8 nm, such as less than or about 7 nm, such as less than or about 6 nm, such as less than or about 5 nm, such as less than or about 4 nm, such as less than or about 2 nm, such as greater than or about 1 nm, or any ranges or values therebetween. Nonetheless, in embodiments, the one or more channels 302 and/or features 301 may have any heights, widths, or aspect ratios discussed above.

Regardless of the feature(s) formed in embodiments, methods according to the present technology may include providing a semiconductor structure 300, which may be a 4F² vertical array, with one or more features 301 to a processing region of a processing chamber, such as one or more processing chambers as discussed above. In embodiments, the processing chamber may be the same chamber in which the one or more features was former, or the semiconductor structure 300 may be transferred to a separate processing chamber. In the illustrated embodiments, one or more oxide layers 303 may be formed around the respective feature 301. In embodiments, the oxide layer 303 may be a gate oxide, or a protective liner, based upon the desired structure. Thus, in embodiments, the oxide 303 may include dielectric material as known in the art, such as silicon oxide, silicon dioxide, other dielectrics as known in the art, and the like. However, it should be understood that oxide 303 may also include other liner materials based upon the desired device.

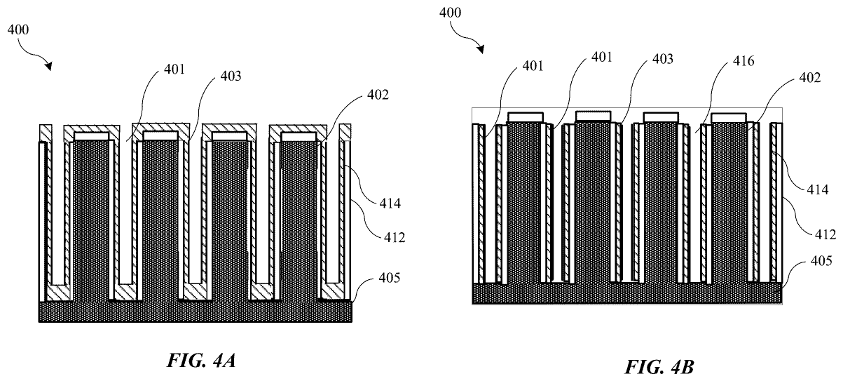

Nonetheless, at operation 210, one or more molybdenum layers 314 may be formed within feature 301. The molybdenum layer(s) 314 may be formed utilizing any method as known in the art, and in embodiments, may be formed in thin sheets, as may be discussed in greater detail in regards to FIGS. 4A and 4B. In FIGS. 3A and 3B, the molybdenum layer(s) 314 may be utilized to fill feature 301, which may be in the form of a trench. However, as known in the art molybdenum is highly susceptible to inter-diffusion from oxygen and/or nitrogen. Previously, due to the negative impacts of inter-diffusion, molybdenum has not been utilized for metallized feature formation, as passivation, particularly with limited feature size, has not been possible. For instance, in the illustrated embodiment of FIGS. 3A and 3B, inter-diffusion of oxygen or nitrogen from an overlying dielectric layer 312 would shift the work function of the material.

However, the present technology has surprisingly found that by carefully forming a layer of a nitrogen-containing material utilizing a controlled diffusion or deposition process over an exposed surface of a molybdenum-containing layer, a protective conformal layer 316 of MoₓN_{y} may be formed over the exposed surface of the molybdenum containing layer in a self-aligned fashion, at operation 215. Thus, the protective layer 316 of the present technology may fully protect an exposed surface of the molybdenum layer 314 without reducing thickness of the molybdenum layer 314 (e.g. the protective layer 316 does not consume significant portions of the molybdenum layer 314) or reduce the available feature area (e.g. does not deposit large thicknesses of nitrogen-containing material). Namely, the present technology has found that by utilizing a reactive nitrogen-containing precursor in the presence of the discussed processing conditions, the nitrogen may react with an exposed surface of the molybdenum-containing material, to form a MoₓN_{y} protective layer. It is also possible to use a combination of hydrogen-containing materials and nitrogen containing materials, either co-flowed or sequentially, to remove oxygen in an air exposed molybdenum surface (e.g. a surface that contains MoₓO_{y}) and replace the oxygen with nitrogen to form a MoₓN_{y} protective layer. Thus, a robust protective layer may be formed without adding additional thickness to the one or more molybdenum-containing layers or consuming additional molybdenum.

In embodiments, protective layer 316 may be formed overlying an exposed surface of the molybdenum layer 314. The exposed surface may include a vertically extending surface, as will be discussed in greater detail in regards to FIGS. 4A and 4B, or may be a horizontally extending surface, as illustrated in FIGS. 3A and 3B. However, it should be understood that, in embodiments, the exposed surface or surfaces may extend in one or more directions, and may include any surface suitable for formation of a nitrogen-containing layer thereon. The protective layer 316 may be formed by providing one or more nitrogen-containing precursor suitable for reacting with the exposed surface of the molybdenum-containing layer. In embodiments, the nitrogen-containing precursor may be a diffusion or deposition precursor, reactive gas, or ion thereof, and may be or include ammonia (NH₃) and mixtures of molecular nitrogen and hydrogen (N₂+H₂), among other nitrogen-containing precursors useful in semiconductor processing. Furthermore, it should be clear that, precursors as discussed herein may refer to a reactive gas, an ion, a radical, or a combination thereof, as both plasma and/or reactive gas processes may be utilized. The nitrogen-containing precursors may also include at least one carrier gas. Embodiments of carrier gases may include molecular nitrogen (N₂), hydrogen, helium, xenon, or argon, among other carrier gases useful in semiconductor processing. However, in embodiments, it should be understood that the reactive nitrogen-containing precursor may not utilize a plasma process, and may form protective layer 316 by contacting the molybdenum layer 314 with one or more of the nitrogen-containing precursors discussed above, and thermally driven, which will be discussed in greater detail below. Furthermore, in embodiments, the formation of the MoₓN_{y} protective layer may utilize a combination of a thermally driven process and a plasma assisted process.

When utilized, the plasma may be generated by delivering plasma power to the deposition or diffusion precursors that have flowed into the processing region. In some embodiments, the plasma power may be delivered by a power source that is electrically coupled to at least one electrode within the semiconductor processing chamber. In embodiments, the power source may deliver power to the at least one electrode, which creates an electric field in the processing region of the semiconductor processing chamber that energizes the precursors to form the plasma, or may include a remote plasma source. In embodiments, the power source may include a RF power source, a microwave power source, or any other source capable of generating ions or radicals. The plasma power delivered to the precursors may be less than or about 2000 Watts, less than or about 1750 Watts, less than or about 1500 Watts, less than or about 1250 Watts, less than or about 1000 Watts, less than or about 900 Watts, less than or about 800 Watts, less than or about 700 Watts, less than or about 600 Watts, less than or about 575 Watts, less than or about 550 Watts, less than or about 525 Watts, less than or about 500 Watts, or greater than or about 50 Watts, greater than or about 75 Watts, greater than or about 100 Watts, greater than or about 150 Watts, greater than or about 200 Watts, greater than or about 250 Watts, greater than or about 300 Watts, greater than or about 350 Watts, greater than or about 400 Watts, greater than or about 450 Watts, or any ranges or values therebetween. The frequency of the power delivered to the precursors may be 13.56 MHz in one non-limiting example. In some embodiments, the plasma power delivered to the precursors may be supplied continuously, while in additional embodiments, the plasma power may be pulsed. In pulsed embodiments, the delivered RF plasma power may have a pulsing frequency that may be less than or about 10 kHz, and may be less than or about 9 kHz, less than or about 8 kHz, less than or about 7 kHz, less than or about 6 kHz, less than or about 5 kHz, less than or about 4 kHz, less than or about 3 kHz, less than or about 2 kHz, less than or about 1 kHz, or less.

In embodiments, the deposition and/or reaction of the nitrogen-containing precursor may be conducted at a temperature that influences the deposition or diffusion rate of the material and the formation of the MoₓN_{y} layer. For example, the processing region of the semiconductor processing chamber may be characterized by a deposition or diffusion temperature (e.g. referred to as a contacting or processing temperature herein) from about room temperature up to about 1000° C., such as less than or about 900° C., such as less than or about 800° C., such as less than or about 750° C., less than or about 700° C., less than or about 650° C., less than or about 600° C., less than or about 550° C., less than or about 525° C., less than or about 500° C., less than or about 450° C., less than or about 400° C., less than or about 350° C., less than or about 300° C., less than or about 250° C., less than or about 200° C., less than or about 150° C., less than or about 100° C., less than or about 50° C., or greater than or about 50° C., greater than or about 100° C., greater than or about 150° C., greater than or about 200° C., greater than or about 250° C., greater than or about 300° C., greater than or about 350° C., greater than or about 400° C., greater than or about 425° C., greater than or about 450° C., or greater than or about 475° C., or any ranges or values therebetween. In embodiments, by depositing or diffusing at temperatures below or about 700° C., or even 550° C., the present technology may protect device thermal budgets while also provide excellent reaction of the nitrogen-containing precursor with a surface of molybdenum layer 314.

A flow rate for one or more of the gasses discussed may be greater than or about 1 sccm, greater than or about 10 sccm, greater than or about 20 sccm, greater than or about 30 sccm, greater than or about 40 sccm, 50 sccm, greater than or about 100 sccm, greater than or about 250 sccm, greater than or about 500 sccm, greater than or about 750 sccm, greater than or about 1000 sccm, greater than or about 1250 sccm, greater than or about 1500 sccm, greater than or about 1750 sccm, greater than or about 2000 sccm, greater than or about 2250 sccm, greater than or about 2500 sccm, greater than or about 2750, greater than or about 3000 sccm, greater than or about 4000 sccm, greater than or about 5000 sccm, greater than or about 10000 sccm, or more, or any ranges or values therebetween. Additionally or alternatively, any flow rate may be utilized suitable for the selected gas phase dopant or radical thereof. A flow rate of the dopant gas may depend on the target doping concentration, as well as other process conditions such as temperature and pressure.

In embodiments, the molybdenum layer 314 may be contacted for a period of time of greater than or about 1 second up to about 600 seconds, such as greater than or about 5 seconds, such as greater than or about 10 seconds, such as greater than or about 15 seconds, such as greater than or about 60 seconds, such as greater than or about 90 seconds, such as greater than or about 120 seconds, such as greater than or about 180 seconds, such as greater than or about 210 seconds, such as greater than or about 240 seconds, or such as less than or about 570 seconds, such as less than or about 540 seconds, such as less than or about 510 seconds, such as less than or about 480 seconds, such as less than or about 450 seconds, such as less than or about 420 seconds, such as less than or about 390 seconds, such as less than or about 360 seconds, such as less than or about 330 seconds, such as less than or about 300 seconds such as less than or about 270 seconds, such as less than or about 240 seconds such as less than or about 210 seconds, such as less than or about 180 seconds, or any ranges or values therebetween. In embodiments, the contacting may be repeated for two or more cycles, utilizing any one or more of the above time ranges.

Namely, by controlling the processing conditions as discussed herein, an adequate layer of nitrogen (and therefore MoₓN_{y}) for protecting the molybdenum layer 314 from inter-diffusion may be formed without overburdening the layer with nitrogen. Thus, in embodiments, less than or about 50% of a thickness of the molybdenum layer 314 (measured from the deposition or diffusion surface towards an opposed surface) may be MoₓN_{y} after reaction, such as less than or about 45%, such as less than or about 40%, such as less than or about 35%, such as less than or about 30%, such as less than or about 25%, such as less than or about 20%, such as less than or about 15%, such as less than or about 10%, or any ranges or values therebetween. Stated differently, in embodiments, the MoₓN_{y} layer may have a thickness, dependent upon device requirements, of from about 1 Å to about 100 Å, such as greater than or about 2 Å, such as greater than or about 3 Å, such as greater than or about 4 Å, such as greater than or about 5 Å, such as greater than or about 10 Å, such as greater than or about 15 Å, such as greater than or about 20 Å, such as greater than or about 25 Å, such as greater than or about 30 Å, such as greater than or about 35 Å, such as greater than or about 40 Å, such as greater than or about 45 Å, such as greater than or about 50 Å, such as greater than or about 60 Å, such as greater than or about 70 Å, such as greater than or about 80 Å, such as greater than or about 90 Å, or such as less than or about 100 Å, less than or about 90 Å, less than or about 80 Å, less than or about 70 Å, less than or about 60 Å, less than or about 50 Å, less than or about 40 Å, less than or about 30 Å, less than or about 20 Å, less than or about 10 Å, or any ranges or values therebetween.

In embodiments, the structure may be pre-cleaned prior to reaction with the nitrogen-containing precursor with a wet or dry cleaning process, and may be an integrated pre-clean within the processing chamber. However, as the affinity for the molybdenum layer 314 for nitrogen is higher than the affinity for oxygen, cleaning operations may not be necessary, in embodiments. Namely, the nitrogen may replace the diffused oxygen, with or without assistance of additional hydrogen-containing materials, or may form a protective layer of MoₓO₂N_{y}, which also prevents inter-diffusion.

While thus far the formation of the protective layer has been discussed in regards to molybdenum contained in the pre-formed molybdenum layer, in embodiments, it may also be possible to form a protective MoₓN_{y} layer by depositing a MoₓN_{y} layer over the molybdenum-containing layer. In embodiments, a molybdenum-containing precursor may be co-flowed or sequentially flowed with the nitrogen-containing precursor, and any additional process gasses discussed above, according to the methods discussed herein. When forming a MoₓN_{y} layer over the molybdenum containing layer utilizing a molybdenum-containing precursor, it may be necessary to remove any MoO formed on the molybdenum surface, or covert any oxide present to Mo, prior to deposition of the MoₓN_{y} layer.

Nonetheless, in embodiments, optional operation 220 may include forming a dielectric material 312 over protective layer 316. Namely, as discussed above, the protective layer 316 may passivate the surface of the molybdenum layer 314, preventing inter-diffusion of oxygen and/or nitrogen from the dielectric into the molybdenum-containing layer, and allowing a dielectric material to be placed directly over the protective layer. Suitable dielectric materials 312 may include any one or more of the dielectric materials discussed above, and/or may include one or more of SiO, SiN, SION, SiOCN, SiCN, SiOC, combinations thereof, and other dielectric materials as known in the art. Thus, in the illustrate embodiment of FIGS. 3A and 3B, molybdenum layer 314 may be utilized as a trench fill material, followed by formation of a dielectric material layer 312 over the trench, prior to further processing. The structures and processes of the present technology allow molybdenum to be utilized for such an operation, allowing for improved properties within the structure.

As a further example, FIGS. 4A and 4B illustrate further examples of structures and methods according to the present technology. However, as discussed above, it should be clear that the examples are for illustrative purposes only, and that methods and systems discussed herein may be utilized when it is desired to have a molybdenum-containing layer adjacent to one or more dielectric layers. Nevertheless, as discussed above, the methods and systems discussed herein may be further well suited for the structures discussed herein, as the methods and systems discussed herein do not substantially increase the thickness and/or decrease the molybdenum content of the layer, unlike prior attempts.

Referring back to FIG. 4A, in embodiments, the one or more molybdenum layers 414 may be utilized to form one or more word line sheets. However, in addition to being prone to inter-diffusion, molybdenum also exhibits high instances of defects or altered electrical properties due to processing damage. Thus, in embodiments, it may be desired to form protective layer 416 prior to one or more etch processes. Thus, as illustrated in FIG. 4B, in embodiments, protective layer 416 may be formed according to one or more of the processes discussed above, along the exposed surface of molybdenum layer 414. After formation of protective layer 416, the bottom of molybdenum layer 414 may be “punched”, utilizing one or more etching processes, in order to prevent shorting between adjacent channels. However, it should be clear that other etching processes may also be utilized.

In embodiments, it may not be necessary to protect the molybdenum layer prior to one or more etch operations. However, in embodiments, it is desired to fill the remainder of the feature 401 with a dielectric material 412, or protect the molybdenum layer from atmospheric oxygen (e.g. if leaving an air gap instead of the illustrated dielectric material). Thus, if the protective layer 416 is not yet formed, protective layer 416 formation may occur prior to a dielectric material fill operation 220, or a capping operation, if the dielectric material is replaced with an air gap.

Nevertheless, while the protective layer 316 and/or 416 herein may be formed in a manner that provides for excellent material properties even in the presence of the MoₓN_{y} layer, the present technology has surprisingly found that rapid thermal processing may allow for the decomposition of the MoₓN_{y} to metallic Mo and diffused nitrogen (such as into an adjacent dielectric layer). Such embodiments may provide further improvements in material properties, such as further improved resistivity. Thus, in embodiments, it may be desirable to conduct an optional post thermal treatment, after the formation of one or more dielectric layers, at a temperature range of about 300° C. to about 1200° C., or such as greater than or about 350° C. greater than or about 400° C., greater than or about 450° C., greater than or about 500° C., greater than or about 550° C., greater than or about 600° C., greater than or about 650° C., greater than or about 700° C., greater than or about 750° C., greater than or about 800° C., greater than or about 850° C., greater than or about 900° C., greater than or about 950° C., greater than or about 1000° C., greater than or about 1050° C., or such as less than or about 1200° C., less than or about 1150° C., less than or about 1100° C., less than or about 1050° C., less than or about 1000° C., or any ranges or values therebetween.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

What is claimed is:

1. A semiconductor processing method comprising:
providing a high aspect ratio semiconductor structure within a semiconductor processing chamber, and wherein one or more molybdenum-containing layers are formed on the semiconductor structure;
providing a nitrogen-containing precursor to a processing region of the semiconductor processing chamber;
contacting the one or more molybdenum-containing layers with the nitrogen-containing precursor, wherein the contacting: nitrides a surface of the one or more molybdenum-containing layers, forming a protective layer over the one or more molybdenum-containing layers, or deposits the protective layer over the one or more molybdenum-containing layers.

2. The method of claim 1, further comprising depositing one or more dielectric layers over the protective layer or etching the one or more molybdenum-containing layers.

3. The method of claim 2, further comprising thermally annealing the molybdenum-containing layers at a temperature of less than or about 1000° C.

4. The method of claim 1, wherein a temperature within the semiconductor processing chamber is maintained at less than or about 1000° C.

5. The method of claim 1, wherein the contacting is a plasma process, thermally driven, or a combination thereof.

6. The method of claim 1, wherein the contacting further comprises a hydrogen containing precursor, a molybdenum-containing precursor, or a combination thereof.

7. The method of claim 1, wherein the nitrogen-containing precursor comprises NH₃, N₂, N₂ and H₂, or a combination thereof.

8. The method of claim 1, wherein the protective layer forms a conformal coating over the molybdenum-containing layer.

9. A method of forming a vertical cell dynamic random-access memory (DRAM) array, comprising:
etching a substrate to form one or more shallow trench isolations and a plurality of vertically extending channels;
forming one or more molybdenum-containing layers within one or more of the shallow trench isolations;
contacting an exposed surface of the one or more molybdenum-containing layers with a nitrogen-containing precursor, wherein the contacting: nitrides a surface of the one or more molybdenum-containing layers, forming a protective layer over the one or more molybdenum-containing layers, or deposits the protective layer over the one or more molybdenum-containing layers; and
forming one or more dielectric layers over the protective layer.

10. The method of claim 9, wherein a temperature during contacting is maintained at less than or about 1000° C.

11. The method of claim 9, wherein the protective layer forms a conformal coating over the molybdenum-containing layer.

12. The method of claim 9, wherein the contacting is a plasma process, thermally driven, or a combination thereof.

13. The method of claim 9, wherein the contacting further comprises a hydrogen containing precursor, a molybdenum-containing precursor, or a combination thereof.

14. The method of claim 9, wherein the nitrogen-containing precursor comprises NH₃, N₂, N₂ and H₂, or a combination thereof.

15. The method of claim 9, wherein the one or more molybdenum-containing layers comprises one or more word lines.

16. The method of claim 15, wherein the one or more word lines comprise one or more word line sheets formed along at least a portion of a sidewall of the one or more vertically extending channels.

17. The method of claim 9, further comprising thermally processing the vertical cell DRAM array after forming the one or more dielectric layers over the protective layer.

18. A memory device, comprising:
a bit line extending in a first direction;
two or more word lines extending in a second direction different than the first direction; and
at least one channel extending between adjacent word lines in a direction generally orthogonal to the first direction and the second direction, the channel having a first end adjacent to the bit line and a second end opposite the first end; and
wherein the two or more word lines comprise a molybdenum-containing material.

19. The memory device of claim 18, further comprising a MoₓN_{y} layer between the molybdenum-containing material and a dielectric material.

20. The memory device of claim 18, wherein the two or more word lines comprise word line sheets or filled trenches.
